(19) United States
(12) Patent Application Publication
(10) Pub. No.: US 2018/0003526 A1
(43) Pub. Date: Jan. 4, 2018

(54) MAGNETIC ENCODER

(71) Applicant: AISIN SEIKI KABUSHIKI KAISHA, Kariya-shi (JP)

(72) Inventor: Eiichiro IWASE, Toyoake-shi (JP)

(73) Assignee: AISIN SEIKI KABUSHIKI KAISHA, Kariya-shi (JP)

(21) Appl. No.: 15/632,889

(22) Filed: Jun. 26, 2017

(30) Foreign Application Priority Data
Jun. 29, 2016 (JP) 2016-129331

(51) Int. Cl. G01D 5/245; G01D 5/14; G01P 3/487; G01R 33/02

(52) U.S. Cl. CPC G01D 5/2454; G01R 33/02; G01D 5/142; G01P 3/487

(57) ABSTRACT

A magnetic encoder includes: an annular magnetic rotor; and a magnetic sensor that faces the magnetic rotor with a predetermined gap therebetween. The magnetic rotor includes a multipole magnetized portion in which an N magnetic pole and an S magnetic pole are alternately provided at a predetermined pitch in a circumferential direction, an origin magnetized portion whose circumferential width is larger than the pitch of the multipole magnetized portion and having the same polarity as an end portion of the multipole magnetized portion in the circumferential direction, and an opposite polar portion which has the opposite polarity to the multipole magnetized portion and the origin magnetized portion and is adjacent to the multipole magnetized portion and the origin magnetized portion. The circumferential width of the opposite polar portion is larger than the pitch of the multipole magnetized portion and smaller than the circumferential width of the origin magnetized portion.

### CROSS REFERENCE TO RELATED APPLICATIONS

This application is based on and claims priority under 35 U.S.C. §119 to Japanese Patent Application 2016-129331, filed on Jun. 29, 2016, the entire contents of which are incorporated herein by reference.

### TECHNICAL FIELD

This disclosure relates to a magnetic encoder in which an annular magnetic rotor includes a multipole magnetized portion where an N magnetic pole and an S magnetic pole are alternately provided and an origin magnetized portion configuring a reference point.

### BACKGROUND DISCUSSION

In the related art, a magnetic encoder is used for detecting a rotational angular position of a rotating body, or the like and an annular magnetic rotor has a multipole magnetized portion and an origin magnetized portion in a circumferential direction (see, for example, Patent Documents JP1995-4987A (Reference 1), JP2003-75192A (Reference 2), and JP2009-25163A (Reference 3)). In the multipole magnetized portion, an N magnetic pole and an S magnetic pole are alternately disposed at a constant pitch. On the other hand, the origin magnetized portion is wider than the pitch of the multipole magnetized portion. The magnetic encoder detects the rotational angular position of the rotating body with the origin magnetized portion as a reference position.

In such a magnetic encoder, since the origin magnetized portion is wider than the pitch of the multipole magnetized portion, a magnetic flux density distribution of the origin magnetized portion is different from a magnetic flux density distribution of the multipole magnetized portion. Among the multipole magnetized portions, the magnetic poles adjacent to the origin magnetized portion are affected by the origin magnetized portion and magnetic flux waveforms thereof are disturbed. For this reason, an error may occur in the rotational angular position detected by a magnetic sensor in the multipole magnetized portion.

In order to suppress disturbance of the magnetic flux waveform in the multipole magnetized portion, there are techniques such as a technique (for example, Reference 1) for forming a groove in the origin magnetized portion by integral molding or cutting, a technique (for example, Reference 2) for magnetizing the origin magnetized portion into an island shape to obtain an irregular magnetic pole, and a technique (for example, Reference 3) in which a narrow buffer pole is provided adjacent between the origin magnetized portion and the multipole magnetized portion.

However, in the technique described in Reference 1, it is difficult to align a groove processing position and a magnetization position in the origin magnetized portion, and in the technique described in Reference 2, it is difficult to magnetize an irregular magnetic pole with respect to the origin magnetized portion.

In addition, in the technique described in Reference 3, a buffer pole having an opposite polarity narrower than the pitch of the multipole magnetized portion or the origin magnetized portion is adjacent to a wider origin magnetized portion. For this reason, the buffer pole is positioned in a large magnetic field and the buffer pole receives a large magnetic flux in the opposite direction from the surroundings. As a result, the buffer pole has low magnetic stability and is easily demagnetized by an external magnetic field and heat.

Thus, a need exists for a magnetic encoder which is not susceptible to the drawback mentioned above.

### SUMMARY

A feature of a magnetic encoder according to an aspect of this disclosure resides in that the magnetic encoder includes an annular magnetic rotor and a magnetic sensor that faces the magnetic rotor with a predetermined gap therebetween, in which the magnetic rotor includes a multipole magnetized portion where an N magnetic pole and an S magnetic pole are alternately provided at a predetermined pitch in a circumferential direction, an origin magnetized portion whose circumferential width is larger than the pitch of the multipole magnetized portion and having the same polarity as an end portion of the multipole magnetized portion in the circumferential direction, and an opposite polar portion which has the opposite polarity to the multipole magnetized portion and the origin magnetized portion and is adjacent to the multipole magnetized portion and the origin magnetized portion, in which the circumferential width of the opposite polar portion is larger than the pitch of the multipole magnetized portion and smaller than the circumferential width of the origin magnetized portion.

### BRIEF DESCRIPTION OF THE DRAWINGS

The foregoing and additional features and characteristics of this disclosure will become more apparent from the following detailed description considered with the reference to the accompanying drawings, wherein:

FIG. 1 is a perspective view of a main part of a magnetic encoder of a first embodiment;

FIG. 2 is a longitudinal sectional view of FIG. 1;

FIG. 3 is a perspective view of a main part of the magnetic encoder of a comparative example;

FIG. 4 is a graph showing a distribution of a magnetic flux density in the magnetic encoder of the comparative example;

FIG. 5 is a graph showing the distribution of the magnetic flux density in the first embodiment;

FIG. 6 is a graph showing a change in an angular pitch error of the first embodiment and the comparative example; and

FIG. 7 is a perspective view of a main part of a magnetic encoder of a second embodiment.

### DETAILED DESCRIPTION

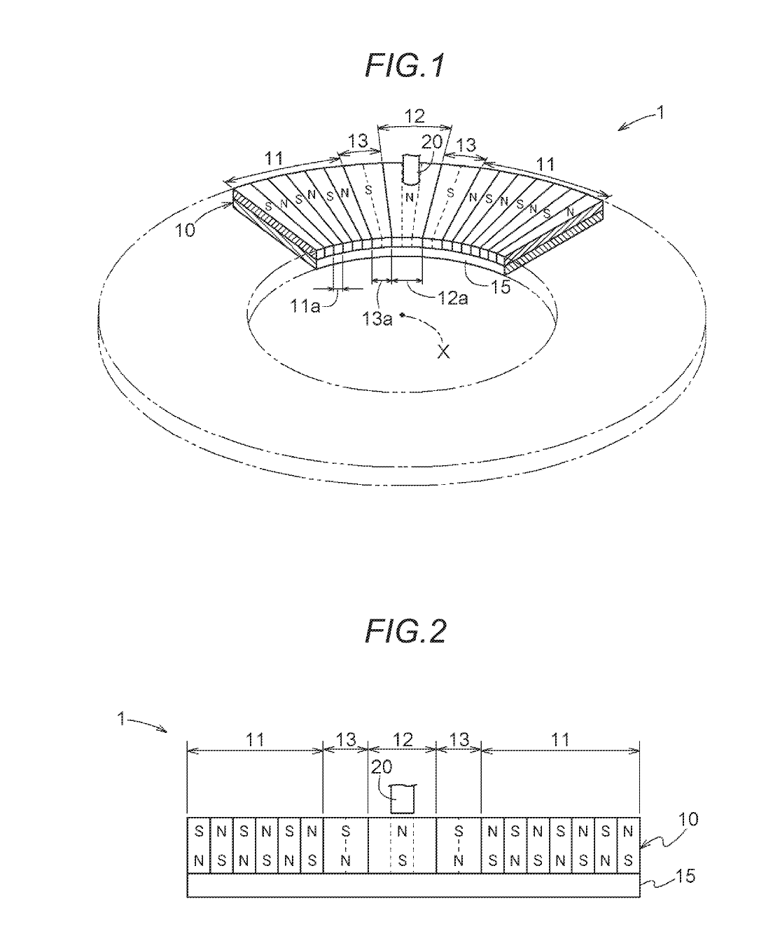

As shown in FIG. 1, a magnetic encoder 1 includes an annular magnetic rotor 10 and a magnetic sensor 20 that faces the magnetic rotor 10 with a predetermined gap therebetween. The magnetic sensor 20 detects a rotational angular position from a change in a magnetic flux generated by rotation of the magnetic rotor 10. For the magnetic sensor 20, for example, a Hall element or a magnetoresistive element is used.

The magnetic rotor 10 includes a multipole magnetized portion 11, an origin magnetized portion 12, and an opposite polar portion 13 in the circumferential direction around a rotational axis X as a center. In the multipole magnetized portion 11, the origin magnetized portion 12, and the opposite polar portion 13, for example, a rubber magnet or a plastic magnet containing filament magnetic powder is used and is integrally molded. A magnetic body plate 15 is disposed on the back of the magnetic rotor 10. By providing the magnetic body plate 15, the magnetic force of the magnetic rotor 10 is improved. In addition, in a case where a rubber magnet is used for the magnetic rotor 10, the magnetic body plate 15 can maintain the form of the magnetic rotor 10.

In the multipole magnetized portion 11, the N magnetic pole and the S magnetic pole are alternately provided at a predetermined pitch 11a in the circumferential direction. The origin magnetized portion 12 is provided as a reference position (origin) for detecting a rotational angular position and is configured with magnetic poles with a circumferential width 12a larger than the pitch 11a of the multipole magnetized portion 11 and having the same polarity as the end portion in the circumferential direction of the multipole magnetized portion 11. The opposite polar portion 13 is configured with magnetic poles adjacent to the multipole magnetized portion 11 and the origin magnetized portion 12 and having the opposite polarity to the multipole magnetized portion 11 and the origin magnetized portion 12. The opposite polar portion 13 has a circumferential width 13a larger than the pitch 11a of the multipole magnetized portion 11 and smaller than the circumferential width 12a of the origin magnetized portion 12. Here, the width refers to the same circumferential length of the magnetic rotor 10 (for example, a circumferential length on an inner diameter side of the magnetic rotor 10 shown in FIG. 1) and the circumferential length is defined by a magnetic pole angle.

As shown in FIG. 1, in the present embodiment, in the magnetic rotor 10, the circumferential width 13a of the opposite polar portion 13 is set to 2 times the pitch 11a of the multipole magnetized portion 11, and the circumferential width 12a of the origin magnetized portion 12 is set to 3 times the pitch 11a of the multipole magnetized portion 11. The outer shape of the magnetic rotor 10 or the magnetic pole angle of each magnetic pole is appropriately determined according to various conditions such as a diameter of a rotating member to be applied.

The annular magnetic rotor 10 is configured, for example, to have magnetization areas each of which is set to 3.75° in the circumferential direction and include 96 of the magnetization areas (49 N magnetic pole areas and 49 S magnetic pole areas) evenly divided in the circumferential direction over the entire circumference. In an example shown in FIG. 1, each magnetization angle of the N magnetic pole and the S magnetic pole of the multipole magnetized portion 11 is 3.75°, the origin magnetized portion 12 is magnetized to the N magnetic pole, and the magnetization angle thereof is set to 11.25°. In addition, the opposite polar portion 13 is magnetized to the S magnetic pole and the magnetization angle thereof is set to 7.5°.

Thus, among the 96 areas, the origin magnetized portion 12 occupies 3 areas having the N magnetic pole and the opposite polar portion 13, which is disposed adjacent to both sides of the origin magnetized portion 12, occupies a total of 4 areas having the S magnetic pole. The multipole magnetized portion 11 occupies the remaining 89 areas. Here, since the number of areas of the multipole magnetized portion 11 is an odd number other than 1, it is possible to dispose the N magnetic pole in two areas adjacent to the opposite polar portion 13 having the S magnetic pole in the multipole magnetized portion 11. In this way, since the origin magnetized portion 12 and the opposite polar portion 13 can be disposed without changing the pitch 11a of the multipole magnetized portion 11, the magnetic rotor 10 can be configured easily.

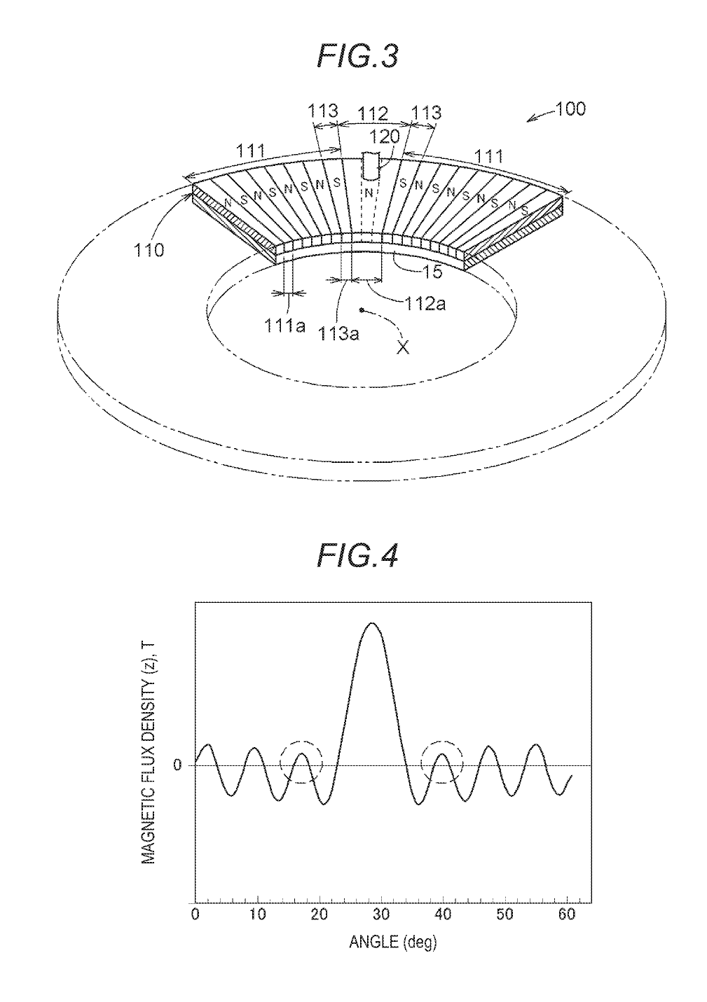

As a comparative example, FIG. 3 shows a magnetic encoder 100. A magnetic rotor 110 includes a multipole magnetized portion 111 and an origin magnetized portion 112. A width 112a of the origin magnetized portion 112 is set to 3 times a pitch 111a of the multipole magnetized portion 111. The pitch 111a is the same as the pitch 11a of the present embodiment. End portions 113 of the multipole magnetized portions 111 are adjacent to the origin magnetized portion 112 in the circumferential direction. Since the end portion 113 is a part of the multipole magnetized portion 111, a width 113a is equal to the pitch 111a.

FIG. 4 shows a distribution of a component of the magnetic flux density in a plane perpendicular direction at the position of a magnetic sensor 120 by the magnetic encoder 100 (FIG. 3) of the comparative example. As the magnetic rotor 110, an annular body having an outer diameter of φ55 mm and an inner diameter of φ40 mm is used. The magnetic flux density is measured at a position (the position of the magnetic sensor 120) with an air gap of 1.5 mm in the direction of the rotation axis X from the position of φ47.4 mm of the magnetic rotor 110. In FIG. 4, the magnetic flux density is offset in a minus direction in left and right mountain-shaped waveforms (the portion surrounded by the broken line) adjacent to a central large mountain-shaped waveform corresponding to the origin magnetized portion 12. For this reason, the magnetic flux density becomes lower than the detection sensitivity of a magnetic sensor 120 and there is a possibility that a detection defect of a magnetic flux pulse may occur in the magnetic sensor 120.

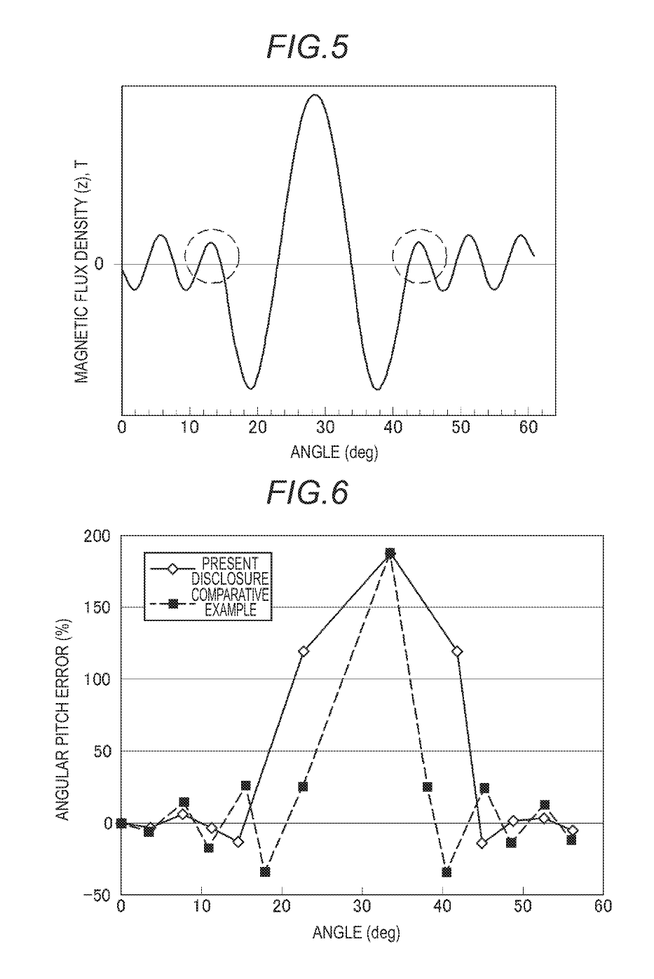

FIG. 5 shows a distribution of a component of the magnetic flux density in the plane perpendicular direction at the position of the magnetic sensor 20 by the magnetic encoder 1 (FIG. 1) of the present embodiment. The air gap (1.5 mm) between the magnetic rotor 10 and the magnetic sensor 20, and the outer diameter (φ55 mm), the inner diameter (φ40 mm), and a measurement position of the magnetic flux density (φ47.4 mm) of the magnetic rotor 10 are the same as the comparative example.

As shown in FIG. 5, in the mountain-shaped waveform (the portion surrounded by the broken line) adjacent to the central mountain-shaped waveform corresponding to the origin magnetized portion 12, an offset amount of the magnetic flux density is small compared with FIG. 4. For this reason, there is a low possibility that a detection defect of the magnetic flux pulse may occur in the magnetic sensor 20 when a rotation angle is detected. This is also apparent in FIG. 6 described below.

FIG. 6 is a graph showing a change in an angular pitch error in the first embodiment and the comparative example. Here, the angular pitch error is calculated by dividing the difference between the angular pitch detected upon receiving a change in the magnetic flux density and an actual angular pitch (for example, 3.75°) by the actual angle pitch.

As shown in FIG. 6, in the left and right areas adjacent to a displacement area of the central mountain-shaped waveform corresponding to the origin magnetized portion 12, a swing width of the angular pitch error is smaller in the present embodiment than in the comparative example. This indicates that the angular pitch error in the multipole magnetized portion 11 adjacent to the origin magnetized portion 12 converges more quickly in the present embodiment than in the comparative example.

In this way, by providing the opposite polar portion 13 which is smaller than the width 12a of the origin magnetized portion 12 and wider than the pitch 11a of the multipole magnetized portion 11, a magnetic field in the direction opposite to the origin magnetized portion 12 can be distributed in a range corresponding to the width of the opposite polar portion in the opposite polar portion 13 on both sides of the origin magnetized portion 12. In this way, the large magnetic field distribution generated in the origin magnetized portion 12 becomes in equilibrium with the magnetic field distribution in the opposite direction, and a phenomenon that the magnetic flux of the multipole magnetized portion 11 is offset to the side opposite to the magnetism of the origin magnetized portion 12 is alleviated. As a result, the magnetic encoder 1 has a simple configuration, but the detection precision of the rotation angle can be improved.

In addition, since the width 13a of the opposite polar portion 13 is smaller than the width 12a of the origin magnetized portion 12 but larger than the pitch 11a of the multipole magnetized portion 11, the opposite polar portion 13 is hardly affected by the external magnetic field and is difficult to be demagnetized.

As shown in FIGS. 1 and 2, the magnetic rotor 10 is magnetized in the direction of the rotational axis X and the magnetic sensor 20 is disposed to face the magnetic rotor 10 in the direction of the rotation axis X. In this way, the magnetic sensor 20 can face the surface perpendicular to the direction of the rotation axis X and the gap between the magnetic sensor 20 and the magnetic rotor 10 becomes constant. As a result, since the magnetic sensor 20 can easily detect the magnetic flux from the magnetic rotor 10, the detection precision of the rotational angular position is improved in the magnetic encoder 1.

### Second Embodiment

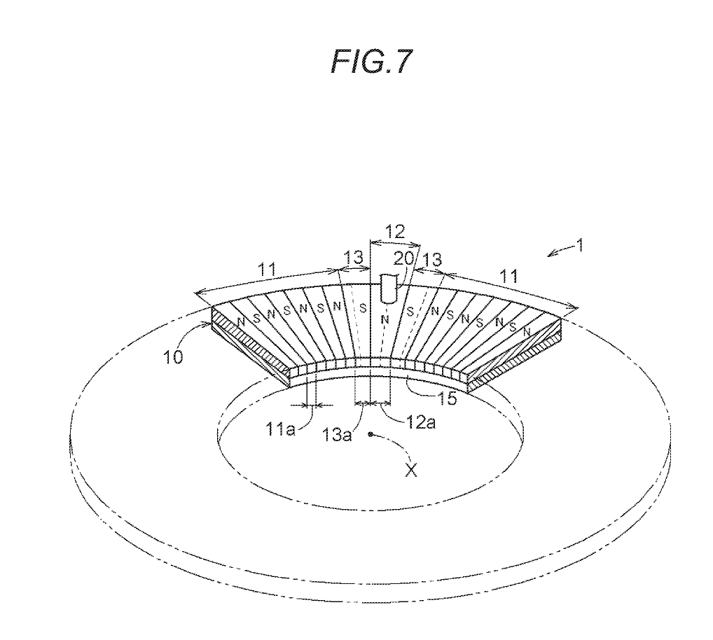

As shown in FIG. 7, in the present embodiment, in the magnetic rotor 10, the width 12a of the origin magnetized portion 12 is set 2 times the pitch 11a of the multipole magnetized portion 11, and the width 13a of the opposite polar portion 13 is set to 1.5 times the pitch 11a of the multipole magnetized portion 11.

Similarly to the first embodiment, in a case where one magnetization area is set to 3.75° and there are 96 magnetization areas in the entire circumference, each magnetic pole angle of the multipole magnetized portion 11 becomes 3.75°, the magnetic pole angle of the origin magnetized portion 12 becomes 7.5°, and the magnetic pole angle of the opposite polar portion 13 is 5.625°.

Thus, among the 96 areas, the origin magnetized portion 12 occupies two areas having the N magnetic pole and the opposite polar portion 13, which is disposed adjacent to both sides of the origin magnetized portion 12, occupies a total of 3 areas having the S magnetic pole. The multipole magnetized portion 11 occupies the remaining 91 areas. Here, since the number of areas of the multipole magnetized portion 11 is an odd number other than 1, it is possible to dispose the N magnetic pole in two areas adjacent to the opposite polar portions 13 having the S magnetic pole in the multipole magnetized portion 11. In this way, also in this embodiment, since the origin magnetized portion 12 and the opposite polar portion 13 can be disposed without changing the pitch 11a of the multipole magnetized portion 11, the magnetic rotor 10 can be configured easily.

### Another Embodiment

(1) The width 12a of the origin magnetized portion 12 and the width 13a of the opposite polar portion 13 are not limited to the above embodiments. If the width 12a of the origin magnetized portion 12 is larger than the pitch 11a of the multipole magnetized portion 11, and the width 13a of the opposite polar portion 13 is larger than the pitch 11a of the multipole magnetized portion 11 and smaller than the width 12a of the origin magnetized portion 12, the width 12a of the origin magnetized portion 12 and the width 13a of the opposite polar portion 13 other than the above embodiments may be used.

(2) In the above embodiments, in the magnetic rotor 10, an example is shown in which the origin magnetized portion 12 has the N magnetic pole and the opposite polar portion 13 has the S magnetic pole, but the origin magnetized portion 12 may have the S magnetic pole and the opposite polar portion 13 may have the N magnetic pole.

(3) In the above embodiments, an example is shown in which the magnetic rotor 10 is magnetized so that a magnetic field is formed in the direction of the rotation axis X, but the magnetic rotor 10 may be configured so that the magnetic field is formed in a radial direction. In that case, the magnetic sensor 20 is disposed to face an outer circumferential surface of the magnetic rotor 10.

(4) In the above embodiments, an example is shown in which the magnetic encoder 1 is configured by stacking the magnetic body plate 15 on the magnetic rotor 10, but the magnetic encoder 1 may have a configuration not having the magnetic body plate 15.

(5) In the above embodiments, an example is shown in which the magnetic rotor 10 is provided with one origin magnetized portion 12, but the origin magnetized portion 12 may be disposed at a plurality of positions in the circumferential direction of the magnetic rotor 10.

The magnetic encoder according to this disclosure can be widely applied to the detection of a position of a rotating body and the like.

A feature of a magnetic encoder according to an aspect of this disclosure resides in that the magnetic encoder includes an annular magnetic rotor and a magnetic sensor that faces the magnetic rotor with a predetermined gap therebetween, in which the magnetic rotor includes a multipole magnetized portion where an N magnetic pole and an S magnetic pole are alternately provided at a predetermined pitch in a circumferential direction, an origin magnetized portion whose circumferential width is larger than the pitch of the multipole magnetized portion and having the same polarity as an end portion of the multipole magnetized portion in the circumferential direction, and an opposite polar portion which has the opposite polarity to the multipole magnetized portion and the origin magnetized portion and is adjacent to the multipole magnetized portion and the origin magnetized portion, in which the circumferential width of the opposite polar portion is larger than the pitch of the multipole magnetized portion and smaller than the circumferential width of the origin magnetized portion.

In the magnetic rotor, since the origin magnetized portion is formed with a width larger than the pitch of the multipole magnetized portion, a magnetic flux density of the origin magnetized portion is larger than that of the multipole magnetized portion. Therefore, in the end portion of the multipole magnetized portion close to the origin magnetized portion in the circumferential direction, a magnetic field distribution in the opposite direction is likely to occur so as to be balanced with a large magnetic field distribution generated in the origin magnetized portion, and the magnetic flux waveform generally tends to be offset in the direction opposite to a magnetic flux direction of the origin magnetized portion. In other words, in the area near the origin magnetized portion among the multipole magnetized portions in the circumferential direction, the change in the magnetic flux density is not even. Then, the magnetic sensor cannot detect the accurate magnetic flux waveform corresponding to the pitch in the multipole magnetized portion, so the detection precision of the rotational angular position by the magnetic sensor decreases.

On the contrary, in this configuration, the magnetic rotor includes the opposite polar portion adjacent to the multipole magnetized portion and the origin magnetized portion having the opposite polarity, and the circumferential width of the opposite polar portion is larger than the pitch of the multipole magnetized portion and smaller than the circumferential width of the origin magnetized portion. In this way, by providing the opposite polar portion which is smaller than the circumferential width of the origin magnetized portion and whose circumferential width is larger than the pitch of the multipole magnetized portion, a magnetic field in the direction opposite to the origin magnetized portion can be distributed in a range corresponding to the circumferential width of the opposite polar portion in the opposite polar portions on both sides of the origin magnetized portion. In this way, the large magnetic field distribution generated in the origin magnetized portion becomes in equilibrium with the magnetic field distribution in the opposite direction, and a phenomenon that the magnetic flux waveform in the multipole magnetized portion is offset in the direction opposite to the magnetic flux direction of the origin magnetized portion is alleviated. As a result, the magnetic encoder has a simple configuration, but the detection precision of the rotational angular position can be improved.

In addition, since the circumferential width of the opposite polar portion is smaller than the circumferential width of the origin magnetized portion but larger than the pitch of the multipole magnetized portion, the opposite polar portion is hardly affected by the external magnetic field and is difficult to be demagnetized.

Another feature of the magnetic encoder according to the aspect of this disclosure resides in that the magnetic rotor is magnetized in a rotational axis direction and the magnetic sensor is disposed so as to face the magnetic rotor in the rotational axis direction.

According to this configuration, a magnetic flux of the magnetic rotor is formed in the rotational axis direction and the magnetic sensor faces the rotational axis direction with respect to the magnetic rotor. In this way, the magnetic sensor can face the surface perpendicular to the rotational axis direction and the gap between the magnetic sensor and the magnetic rotor is constant. As a result, since the magnetic sensor can easily detect the magnetic flux from the magnetic rotor, the detection precision of the rotational angular position is improved in the magnetic encoder.

Another feature of the magnetic encoder according to the aspect of this disclosure resides in that the magnetic rotor has the circumferential width of the opposite polar portion set to 2 times the pitch of the multipole magnetized portion, and the circumferential width of the origin magnetized portion set to 3 times the pitch of the multipole magnetized portion.

In the magnetic encoder, it is common that in the magnetic rotor, magnetic poles (N magnetic pole and S magnetic pole) are disposed in a plurality of even-numbered areas equally divided in the circumferential direction and each magnetic pole of the multipole magnetized portion is configured with one section. In this configuration, the circumferential width of the opposite polar portion is set to 2 times the pitch of the multipole magnetized portion, and the circumferential width of the origin magnetized portion is set to 3 times the pitch of the multipole magnetized portion. In this case, the origin magnetized portion (for example, N magnetic pole) occupies 3 areas, the opposite polar portion (for example, S magnetic pole) disposed adjacent to both sides of the origin magnetized portion occupies a total of 4 areas, and the multipole magnetized portion occupies the remaining plural odd-numbered areas, respectively. In this way, since the number of areas of the multipole magnetized portion is an odd number, it is possible to dispose a magnetic pole having the opposite polarity to the opposite polar portion in two areas adjacent to the opposite polar portion in the multipole magnetized portion. Thus, since the origin magnetized portion and the opposite polar portion can be disposed without changing the pitch of the multipole magnetized portion, the magnetic rotor can be configured easily.

Another feature of the magnetic encoder according to the aspect of this disclosure resides in that the magnetic rotor has the circumferential width of the opposite polar portion set to 1.5 times the pitch of the multipole magnetized portion, and the circumferential width of the origin magnetized portion set to 2 times the pitch of the multipole magnetized portion.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A magnetic encoder comprising:
an annular magnetic rotor; and
a magnetic sensor that faces the magnetic rotor with a predetermined gap therebetween,
wherein the magnetic rotor includes
a multipole magnetized portion in which an N magnetic pole and an S magnetic pole are alternately provided at a predetermined pitch in a circumferential direction,
an origin magnetized portion whose circumferential width is larger than the pitch of the multipole magnetized portion and having the same polarity as an end portion of the multipole magnetized portion in the circumferential direction, and
an opposite polar portion which has the opposite polarity to the multipole magnetized portion and the origin magnetized portion and is adjacent to the multipole magnetized portion and the origin magnetized portion, and
wherein the circumferential width of the opposite polar portion is larger than the pitch of the multipole magnetized portion and smaller than the circumferential width of the origin magnetized portion.

2. The magnetic encoder according to claim 1,
wherein the magnetic rotor is magnetized in a rotational axis direction and the magnetic sensor is disposed so as to face the magnetic rotor in the rotational axis direction.

3. The magnetic encoder according to claim 1,
wherein the magnetic rotor has the circumferential width of the opposite polar portion set to 2 times the pitch of the multipole magnetized portion, and the circumferential width of the origin magnetized portion set to 3 times the pitch of the multipole magnetized portion.

4. The magnetic encoder according to claim 2,
wherein the magnetic rotor has the circumferential width of the opposite polar portion set to 2 times the pitch of the multipole magnetized portion, and the circumferential width of the origin magnetized portion set to 3 times the pitch of the multipole magnetized portion.

5. The magnetic encoder according to claim 1,
wherein the magnetic rotor has the circumferential width of the opposite polar portion set to 1.5 times the pitch of the multipole magnetized portion, and the circumferential width of the origin magnetized portion set to 2 times the pitch of the multipole magnetized portion.

6. The magnetic encoder according to claim 2,
wherein the magnetic rotor has the circumferential width of the opposite polar portion set to 1.5 times the pitch of the multipole magnetized portion, and the circumferential width of the origin magnetized portion set to 2 times the pitch of the multipole magnetized portion.
